(19) United States
(12) Patent Application Publication
(10) Pub. No.: US 2017/0110316 A1
(43) Pub. Date: Apr. 20, 2017

(54) METHOD OF CLEANING SUBSTRATE AND METHOD OF FABRICATING SEMICONDUCTOR DEVICE USING THE SAME

(71) Applicant: SAMSUNG ELECTRONICS CO., LTD., Suwon-si (KR)

(72) Inventors: Mi-hyun PARK, Seongnam-si (KR); Jung-min OH, Incheon (KR); Kyoung-hwan KIM, Yongin-si (KR); In-gi KIM, Hwaseong-si (KR); Hyo-san LEE, Hwaseong-si (KR); Ji-hoon JEONG, Suwon-si (KR); Kyoung-seob KIM, Hwaseong-si (KR); Seok-hoon KIM, Seongnam-si (KR)

(21) Appl. No.: 15/237,646

(22) Filed: Aug. 16, 2016

(30) Foreign Application Priority Data
Oct. 16, 2015 (KR) 10-2015-0144740

(51) Int. Cl. H01L 21/02; H01L 29/06; H01L 29/161; H01L 29/16; C11D 11/00; H01L 29/51; H01L 29/49; H01L 29/66; C11D 1/29; H01L 29/78; H01L 29/08

(52) U.S. Cl. CPC H01L 21/02057; H01L 29/7851; H01L 29/0653; H01L 29/161; H01L 29/1608; H01L 29/0847; H01L 29/517; H01L 29/4966; H01L 29/66545; H01L 29/66795; H01L 29/66636; C11D 1/29; C11D 11/0047

(57) ABSTRACT

A method of cleaning a substrate includes providing the substrate, the substrate including a metal material film, performing physical cleaning of the substrate, performing chemical cleaning of the substrate, and drying a surface of the substrate. Performing the chemical cleaning includes supplying a chemical cleaning solution including an anionic surfactant at a concentration that is equal to or greater than a critical micelle concentration (CMC) onto the surface of the substrate.

### CROSS-REFERENCE TO RELATED APPLICATION

Korean Patent Application No. 10-2015-0144740, filed on Oct. 16, 2015, in the Korean Intellectual Property Office, and entitled: “Method of Cleaning Substrate and Method of Fabricating Semiconductor Device Using the Same,” is incorporated by reference herein in its entirety.

### BACKGROUND

Embodiments relate to a method of cleaning a substrate and a method of fabricating a semiconductor device using the same.

### SUMMARY

Embodiments are directed to a method of cleaning a substrate including providing the substrate, the substrate including a metal material film, performing physical cleaning of the substrate, performing chemical cleaning of the substrate, and drying a surface of the substrate. Performing the chemical cleaning includes supplying a chemical cleaning solution including an anionic surfactant at a concentration that is equal to or greater than a critical micelle concentration (CMC) onto the surface of the substrate.

The anionic surfactant may be a sulfate-based surfactant.

The anionic surfactant may have a structure represented by Formula (1):

(R¹—O)ₐ—(R²—O)_{b}—SO₃NH₄ Formula (1), wherein a and b are each independently an integer of 0 to 120; a and b are not simultaneously 0; R¹ and R² are each independently a C₁ to C₁₈ alkyl group, a C₁ to C₁₈ alkylene group, or a C₆ to C₁₄ arylene group; the C₁ to C₁₈ alkyl group, the C₁ to C₁₈ alkylene group, and the C₆ to C₁₄ arylene group are each independently substituted or unsubstituted; and the repeating unit of —R¹—O— and the repeating unit of —R²—O— are repeated randomly or in a block form.

The anionic surfactant may have a structure represented by Formula (2) or (3):

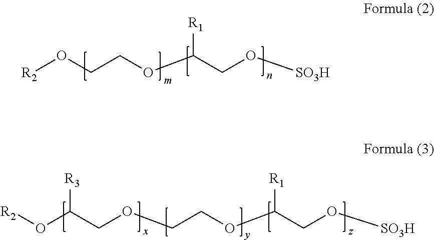

wherein m, n, x, y, and z are each independently an integer of 0 to 120; m and n are not simultaneously 0; x, y, and z are not simultaneously 0; R¹, R², and R³ are each independently a C₁ to C₁₈ alkyl group, a C₁ to C₁₈ alkylene group, or a C₆ to C₁₄ arylene group; and the C₁ to C₁₈ alkyl group, the C₁ to C₁₈ alkylene group, and the C₆ to C₁₄ arylene group are each independently substituted or unsubstituted.

Performing the physical cleaning at least partially overlaps performing the chemical cleaning.

The metal material film may include at least one selected from the group of germanium (Ge), hafnium (Hf), titanium (Ti), tantalum (Ta), tungsten (W), chromium (Cr), gold (Au), silver (Ag), platinum (Pt), palladium (Pd), rhodium (Rh), aluminum (Al), nickel (Ni), molybdenum (Mo), niobium (Nb), zirconium (Zr), strontium (Sr), alloys thereof, nitrides thereof, oxides thereof, and oxynitrides thereof.

The physical cleaning and the chemical cleaning may be simultaneously performed. Performing the physical cleaning may include supplying a physical cleaning solution onto a liquid layer of a chemical cleaning solution.

Performing the chemical cleaning may be terminated simultaneously with or after termination of performing the physical cleaning.

During performing the chemical cleaning, the substrate may be rotated, the chemical cleaning solution may be supplied toward a center of rotation of the substrate, and the liquid layer of the chemical cleaning solution may be formed on the surface of the substrate by the rotation of the substrate.

The supplied chemical cleaning solution may have a pH of about 7 to about 10.

The anionic surfactant supplied onto the surface of the substrate may have a concentration of about 0.0001 M to about 10 M in the cleaning solution.

Embodiments are also directed to a method of fabricating a semiconductor device including forming a metal material film on a substrate, cleaning the substrate, rinsing the substrate, and drying the substrate. Cleaning the substrate includes simultaneously performing physical cleaning and chemical cleaning. The chemical cleaning includes supplying a cleaning solution including an anionic surfactant.

The anionic surfactant may be supplied at a concentration that is equal to or greater than a critical micelle concentration (CMC).

The metal material film may experience a loss rate by the chemical cleaning that is less than 10 nm/min.

In the cleaning of the substrate, a particle removal efficiency (PRE) for particles having a size that is less than 65 nm may be 85% or more.

Embodiments are also directed to a method of fabricating a semiconductor device including providing a substrate, the substrate including a metal material film, conducting a semiconductor device fabrication process on the metal material film, and cleaning the substrate. Cleaning the substrate includes simultaneously performing physical cleaning and chemical cleaning. The chemical cleaning includes supplying a chemical cleaning solution including an anionic surfactant to the substrate from a chemical cleaning solution supplier. The physical cleaning includes supplying a physical cleaning solution to the substrate from a physical cleaning solution supplier, the physical cleaning solution supplier being different from the chemical cleaning solution supplier. The chemical cleaning is begun before or at a same time that the physical cleaning is begun and the chemical cleaning is ended after or at a same time that the physical cleaning is ended.

The semiconductor device fabrication process may be a patterning process that patterns the metal material film.

The anionic surfactant may be included in the chemical cleaning solution at a concentration that is equal to or greater than a critical micelle concentration (CMC). The chemical cleaning solution may have a pH of about 7 to about 10.

In cleaning the substrate, the substrate may be rotated. The chemical cleaning solution may be supplied toward a center of rotation of the substrate, such that the liquid layer of the chemical cleaning solution is formed on the surface of the substrate by the rotation of the substrate. The physical cleaning solution may be supplied onto the liquid layer of the chemical cleaning solution on the substrate.

### BRIEF DESCRIPTION OF THE DRAWINGS

Features will become apparent to those of skill in the art by describing in detail exemplary embodiments with reference to the attached drawings in which:

FIG. 1 illustrates a plan view showing an embodiment of a substrate treating apparatus;

FIG. 2 illustrates a side sectional view showing an example of a substrate cleaning device;

FIG. 3 illustrates a side sectional view showing another example of a substrate cleaning device;

FIG. 4 illustrates a flow chart showing a method of cleaning a substrate according to an embodiment;

FIGS. 5 and 6 illustrate timing diagrams conceptually showing a relationship between a time period for performing physical cleaning and a time period for performing chemical cleaning according to embodiments;

FIGS. 7A to 7C illustrate diagrams for explaining a method of fabricating an integrated circuit element using a cleaning method according to embodiments, FIG. 7A is a plan view of the integrated circuit element intended to be formed, FIG. 7B is a perspective view of the integrated circuit element of FIG. 7A, and FIG. 7C shows sectional views of the integrated circuit element, respectively taken along lines X-X′ and Y-Y′ of FIG. 7A;

FIG. 8A illustrates a plan view of a photomask fabricated using a cleaning method according to embodiments, and FIG. 8B illustrates a sectional view of the photomask, taken along a line B-B′ of FIG. 8A; and

FIG. 9 illustrates a block diagram of an electronic system manufactured using a cleaning method according to embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

It will be also understood that although the terms such as “first”, “second” and the like may be used herein to describe various components, these components should not be limited by these terms. These terms may be used only to distinguish one component from another component. For example, a first component could be termed a second component without departing from the scope of the inventive concept, and a second component could also be termed a first component likewise.

The terminology used herein is only for the purpose of describing specific embodiments and is not intended to limit the inventive concept. As used herein, the singular terms “a,” “an” and “the” are intended to include the plural forms as well, unless the context clearly indicates otherwise. It will be understood that the terms such as “comprises”, “comprising”, “includes”, “including”, “has”, and “having”, when used herein, specify the presence of stated features, numbers, operations, components, parts, or combinations thereof, but do not preclude the presence or addition of one or more other features, numbers, operations, components, parts, or combinations thereof.

Unless otherwise defined, all terms used herein, including technical and scientific terms, have the same meaning as generally understood by those of ordinary skill in the art. It will be understood that terms, such as those defined in generally used dictionaries, should be interpreted as having a meaning that is consistent with meanings understood in the context of the related art, and will not be interpreted in an idealized or overly formal sense unless expressly so defined herein.

When an embodiment can be otherwise realized, specific processes may be performed in a different order from a described order. For example, two processes consecutively described may be substantially simultaneously performed, and may also be performed in an opposite order to a described order.

In the accompanying drawings, variations of illustrated shapes can be anticipated, for example, depending on fabrication techniques and/or tolerances. Thus, embodiments of the inventive concept are not to be construed as being limited to specific shapes of regions illustrated herein, and are to be construed as including, for example, variations of shapes caused in the process of fabrication. As used herein, the term “and/or” includes any and all combinations of one or more of the associated listed items. Expressions such as “at least one of,” when preceding a list of elements, modify the entire list of elements and do not modify the individual elements of the list. In addition, the term “substrate” used herein may refer to a substrate itself, or a stacked structure including a substrate and a certain layer, film, or the like on a surface of the substrate. Further, the term “surface of a substrate” may refer to an exposed surface of a substrate itself, or an outer surface of a certain layer, film, or the like on the substrate.

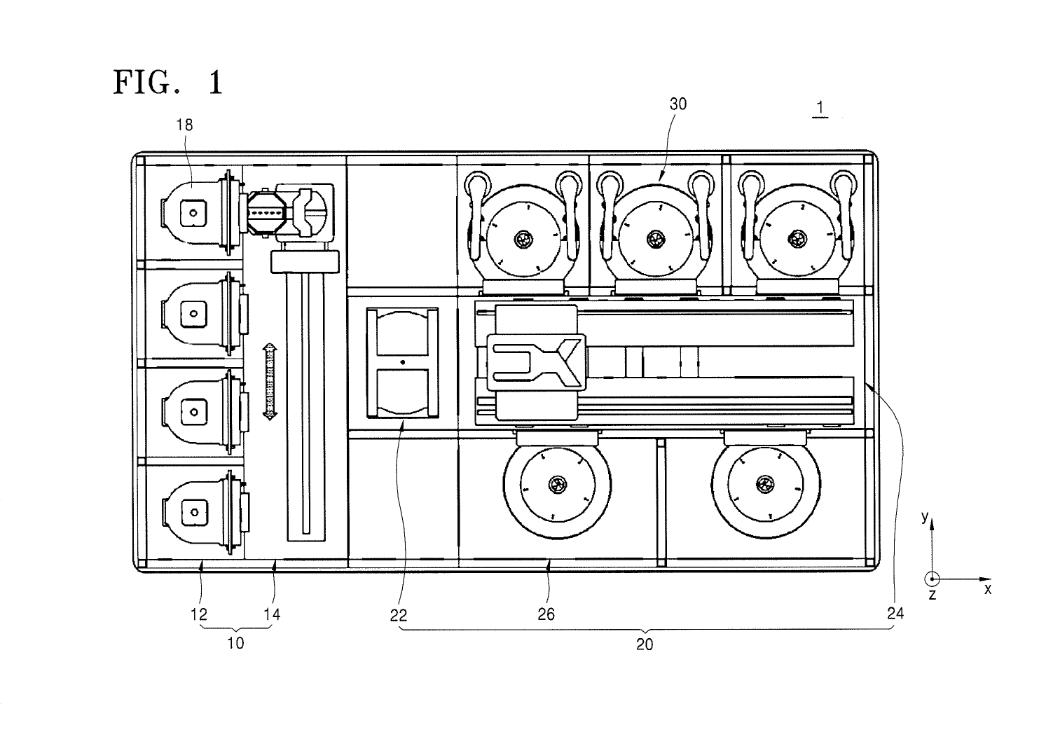

FIG. 1 illustrates a plan view showing an embodiment of a substrate treating apparatus.

Referring to FIG. 1, the substrate treating apparatus 1 may include an index module 10 and a process handling module 20. The index module 10 may include a loading port 12 and a transfer frame 14. In some embodiments, the loading port 12, the transfer frame 14, and the process handling module 20 may be sequentially arranged in a line.

A carrier 18, in which a substrate is received, may be mounted on the loading port 12. The carrier 18 may be a front opening unified pod (FOUP). A plurality of loading ports 12 may be provided. The number of loading ports 12 may be increased or decreased according to process efficiencies and foot print conditions of the process handling module 20, or the like. The carrier 18 may include multiple slots for receiving substrates in a state of being horizontally arranged with respect to the ground.

The process handling module 20 may include a buffer unit 22, a transfer chamber 24, and process chambers 26. The process chambers 26 may be arranged at both sides of the transfer chamber 24. The process chambers 26 may be provided at one side of the transfer chamber 24 and at the other side thereof to be symmetric with respect to the transfer chamber 24.

A plurality of process chambers 26 may be provided at one side of the transfer chamber 24. Some of the process chambers 26 may be arranged along a longitudinal direction of the transfer chamber 24. Some of the process chambers 26 may be stacked. For example, the process chambers 26 may be arranged according to an A×B array at one side of the transfer chamber 24, where A is the number of process chambers 26 provided in a line along an x direction, and B is the number of process chambers 26 provided in a line along a y direction. If four or six process chambers 26 are provided at both sides of the transfer chamber 24, the process chambers 26 may be arranged according to a 2×2 or 3×2 array. The number of process chambers 26 may be increased or decreased. In some embodiments, the process chambers 26 may be provided only at one side of the transfer chamber 24. The process chambers 26 may be provided in a single story at one or both sides of the transfer chamber 24.

The buffer unit 22 may be arranged between the transfer frame 14 and the transfer chamber 24. The buffer unit 22 may provide a space in which a substrate stays before the substrate is transferred between the process chamber 26 and the carrier 18. The transfer frame 14 may transfer a substrate between the carrier 18 mounted on the loading port 12 and the buffer unit 22.

The transfer chamber 24 may transfer a substrate between the buffer unit 22 and the process chamber 26 and between the process chambers 26. A substrate cleaning device 30 that performs a cleaning process of a substrate may be provided in the process chamber 26. The substrate cleaning device 30 may have a various structure according to a kind of cleaning process performed.

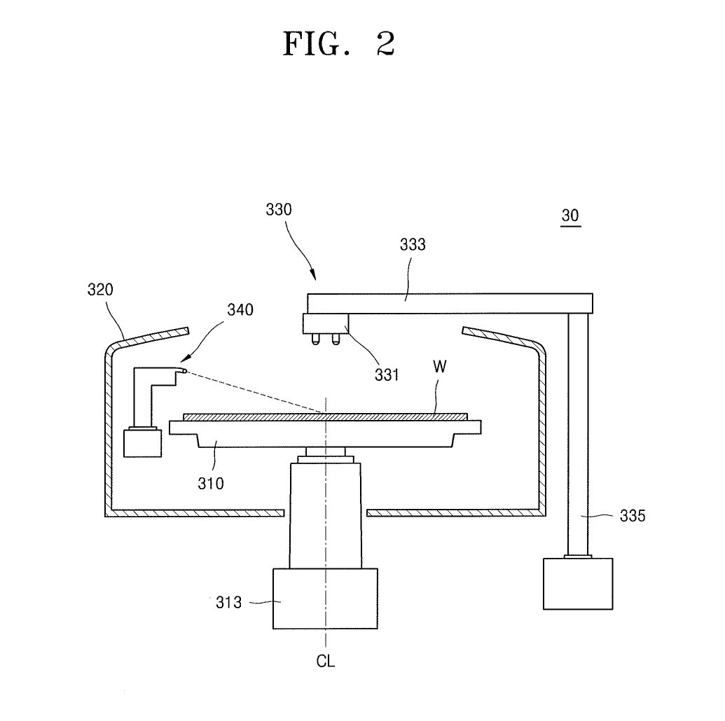

Hereinafter, an example of the substrate cleaning device that cleans a substrate using a cleaning solution will be described. FIG. 2 illustrates a side sectional view showing an example of the substrate cleaning device 30.

Referring to FIG. 2, the substrate cleaning device 30 may include a substrate supporter or supporting unit 310, a housing 320, a first cleaning solution supplier or first cleaning solution supplying unit 330, and a second cleaning supplier or second cleaning solution supplying unit 340.

The substrate supporting unit 310 may support a substrate W to be cleaned on an upper surface thereof. The substrate supporting unit 310 may be coupled to a rotator or rotation unit 313 to rotate the substrate W with respect to a central axis CL of the substrate supporting unit 310. The rotation unit 313 may include a driver such as a motor generating rotational force and a power transmitting unit such as a belt or chain which transmits the rotational force generated from the driver to the substrate supporting unit 310. A spindle may be interposed between the rotation unit 313 and the substrate supporting unit 310 to transmit the rotational force generated from the rotation unit 313 to the substrate supporting unit 310.

The housing 320 may surround the substrate supporting unit 310. The housing 320 may have an open-top shape. The housing 320 may have a structure such that chemicals used for a process can be recovered.

The first cleaning solution supplying unit 330 and the second cleaning solution supplying unit 340 may be respectively configured to supply a physical cleaning solution and a chemical cleaning solution.

The first cleaning solution supplying unit 330 may include a nozzle head 331 that supplies the physical cleaning solution, a nozzle arm 333 supporting the nozzle head 331, and a support spindle 335 that supports the nozzle arm and drives a rotational and/or up-and-down motion of the nozzle arm 333.

The nozzle head 331 may be a nozzle head that is configured to spray extremely fine droplets, for example, a nozzle head configured to spray droplets having a diameter of about 10 μm. In some embodiments, the nozzle head 331 may be configured to remove contamination particles from a surface of the substrate W by spraying ultra-pure water such as deionized water to drive inertial motion thereof. For example, the nozzle head 331 may be a nozzle head used for the physical cleaning as described below.

The nozzle arm 333 may be configured to be rotated along an arc having a center at the support spindle 335. For example, the nozzle arm 333 may be configured to be rotatable along an arc having a center at the support spindle 335 such that the nozzle head 331 is moveable from a center to an edge of the substrate W.

The support spindle 335 may also be configured to be able to perform an up-and-down motion as well as the rotational motion as described above.

The second cleaning solution supplying unit 340 may be configured to supply a chemical cleaning solution. The second cleaning solution supplying unit 340 may be configured to supply the chemical cleaning solution onto the center of the substrate W. For example, the second cleaning solution supplying unit 340 may supply the chemical cleaning solution from an outlet of a nozzle to the center of the substrate W along a path such as indicated by the dotted line of FIG. 2.

Although shown as being arranged in the housing 320 in FIG. 2, in some implementations, the second cleaning solution supplying unit 340 may be arranged outside the housing 320.

When the chemical cleaning solution sprayed from the second cleaning solution supplying unit 340 reaches the surface of the substrate W, the chemical cleaning solution may be coated throughout the entire surface of the substrate W due to rotation of the substrate W. The physical cleaning solution sprayed from the nozzle head 331 of the first cleaning solution supplying unit 330 may be sprayed onto a layer of the chemical cleaning solution instead of directly impacting on the surface of the substrate W. Accordingly, damage of the substrate W due to the physical cleaning may be prevented or minimized. For example, when chemical cleaning using an anionic surfactant was performed together with physical cleaning, it was confirmed that the particle removal efficiency (PRE) for particles having a size that is less than 65 nm was 85% or more.

In particular, when experiments were respectively performed in the case that a concentration of the anionic surfactant was equal to or less than a critical micelle concentration (CMC) and in the case that the concentration of the anionic surfactant was greater than the CMC, the PRE was 87% in the case that the concentration of the anionic surfactant was greater than the CMC while being 58% in the case that the concentration of the anionic surfactant was equal to or less than the CMC. From the results, it could be confirmed that effective cleaning occurred when chemical cleaning was performed simultaneously with the physical cleaning.

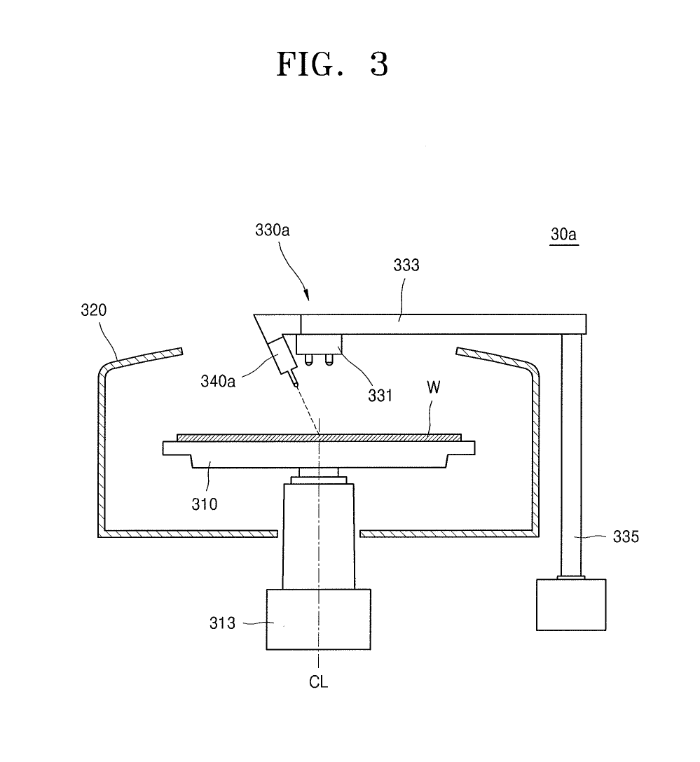

FIG. 3 illustrates a side sectional view showing another example of a substrate cleaning device 30a.

Referring to FIG. 3, the substrate cleaning device 30a is substantially the same as the substrate cleaning device 30 of FIG. 2 except that a second cleaning solution supplying unit 340a is coupled to a first cleaning solution supplying unit 330a. In this embodiment, the second cleaning solution supplying unit 340a may be rotated together with the first cleaning solution supplying unit 330a when the first cleaning solution supplying unit 330a is rotated around the support spindle 335 and above the surface of the substrate W.

On the surface of the substrate W, a position to which the chemical cleaning solution is supplied from the second cleaning solution supplying unit 340a may be substantially the same as a position to which the physical cleaning solution is supplied from the nozzle head 331 of the first cleaning solution supplying unit 330a. The chemical cleaning solution may be directly supplied to a position at which the physical cleaning solution sprayed from the first cleaning solution supplying unit 330a meets the substrate W. Accordingly, physical damage to the substrate W may be more actively minimized or prevented.

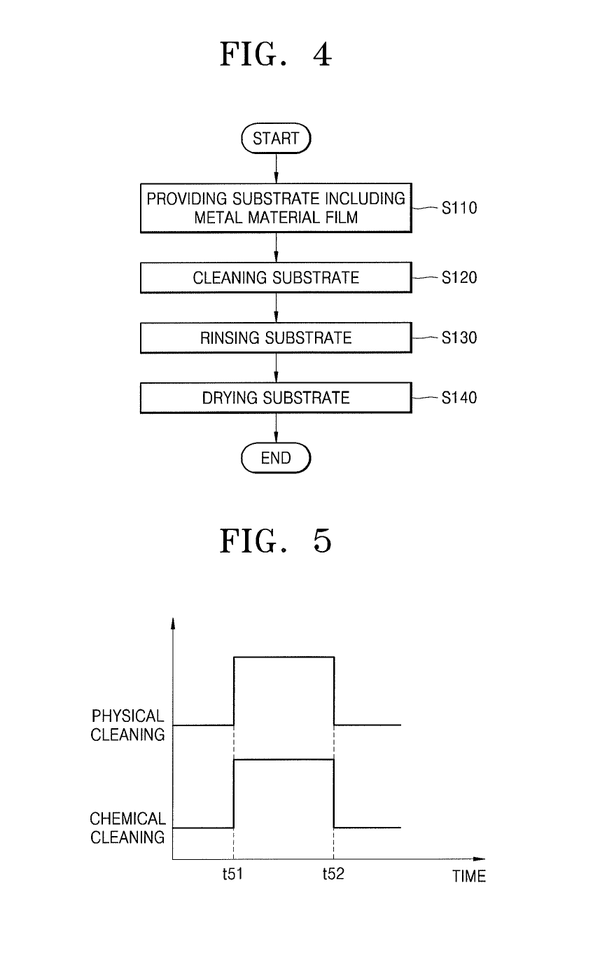

FIG. 4 illustrates a flow chart showing a method of cleaning a substrate according to an embodiment.

Referring to FIG. 4, a substrate including a metal material film is provided (S110). The substrate may be provided into a chamber or into a separate space for cleaning. For example, the substrate may be provided into the substrate cleaning device 30 of FIG. 1.

The metal material film may include, for example, at least one selected from germanium (Ge), hafnium (Hf), titanium (Ti), tantalum (Ta), tungsten (W), chromium (Cr), gold (Au), silver (Ag), platinum (Pt), palladium (Pd), rhodium (Rh), aluminum (Al), nickel (Ni), molybdenum (Mo), niobium (Nb), zirconium (Zr), strontium (Sr), alloys thereof, nitrides thereof, oxides thereof, and oxynitrides thereof. A relatively easily oxidized metal, such as copper (Cu) or aluminum (Al), can be cleaned without a loss of a film thereof by a cleaning method using a cleaning solution such as a general SC-1 solution.

The metal material film may be formed throughout an entire surface of the substrate. In some implementations, the metal material film may have a constant thickness throughout the entire surface of the substrate. In some implementations, the metal material film may have a thickness varying according to a specific rule. In some implementations, the metal material film may be patterned on the surface of the substrate.

The substrate may include a semiconductor substrate including a semiconductor element such as silicon (Si) or germanium (Ge), or a compound semiconductor such as silicon carbide (SiC), gallium arsenide (GaAs), indium arsenide (InAs), or indium phosphide (InP). In some embodiments, the substrate may include a semiconductor substrate, and structures including at least one insulating film and/or at least one conductive region formed on the semiconductor substrate. The at least one conductive region may include, for example, an impurity-doped well, an impurity-doped structure, a metal-containing layer, or the like. The substrate may have various element isolation structures such as a shallow trench isolation (STI) structure.

In some implementations, the substrate may be a display panel such as a liquid crystal substrate or an organic EL substrate, a printed circuit board, a flexible printed circuit board, a solar cell substrate, a sapphire substrate, a quartz substrate, or the like. In some implementations, the sapphire substrate may be a substrate for fabricating a light emitting element. In some implementations, the quartz substrate may be a substrate for fabricating a photomask.

The substrate may be cleaned (S120). The cleaning includes physical cleaning and chemical cleaning.

The term “physical cleaning” refers to a process of removing contaminants, impurities, and particles by applying physical external force through spraying of a fluid or application of ultrasonic waves. In some embodiments, the physical cleaning may include spraying of a fluid. The fluid that makes up a physical cleaning solution may include, for example, deionized water, ultra-pure water, electrolytically ionized water, hydrogen water, and/or ozone water.

To minimize damage to features on the substrate, droplets of the fluid sprayed during the physical cleaning may be adjusted to an extremely small size. For example, the droplets of the fluid sprayed during the physical cleaning may have a diameter of about 10 μm or less.

The physical cleaning may contribute to removing relatively large-sized particles, for example, particles having a size of about 65 nm or more.

The term “chemical cleaning” refers to a process of removing contaminants, impurities, and particles using a chemical agent. The chemical agent (chemical cleaning solution) for the chemical cleaning may be an anionic surfactant.

In particular, the anionic surfactant may have a concentration that is equal to or greater than a critical micelle concentration (CMC). When the anionic surfactant has a concentration that is equal to or greater than the CMC, micelles of the anionic surfactant are formed. Without being bound by a specific theory, it is believed that particles are effectively removed by the micelles surrounding the particles. The CMC may vary according to a kind of anionic surfactant, or the like.

The anionic surfactant may include, for example, (i) sulfonic acid or a salt thereof, including an alkyl, alkylaryl, alkyl naphthalene, alkyl diphenyl ether sulfonic acid, or salt thereof. The sulfonic acid may have six or more carbon atoms in an alkyl substituent, for example, dodecylbenzenesulfonic acid or a sodium salt thereof or an amine salt thereof; (ii) an alkyl sulfate having six or more carbon atoms in an alkyl substituent, for example, sodium lauryl sulfate; (iii) a sulfate ester of a polyoxyethylene monoalkyl ether; or (iv) a long-chain carboxylic acid surfactant or a salt thereof, for example, lauric acid, stearic acid, oleic acid, and an alkali metal or amine salt thereof.

For example, the anionic surfactant may include: an alkyl sulfate, an alkyl ether sulfate, an alkyl sulfonate, an alkaryl sulfonate, an α-olefin sulfonate, an alkylamide sulfonate, an alkaryl polyether sulfate, an alkylamido ether sulfate, an alkyl monoglyceryl ether sulfate, an alkyl monoglyceride sulfate, an alkyl monoglyceride sulfonate, an alkyl succinate, an alkyl sulfosuccinate, an alkyl sulfosuccinamate, an alkyl ether sulfosuccinate, an alkyl amidosulfosuccinate, an alkyl sulfoacetate, an alkyl phosphate, an alkyl ether phosphate, an alkyl ether carboxylate, an alkyl amidoether carboxylate, an N-alkyl amino acid, an N-acyl amino acid, an alkyl peptide, an N-acyl taurate, an alkyl isethionate, a carboxylate salt; or an alkali metal, alkali earth metal, ammonium, amine, or triethanolamine salt thereof.

Alkyl and acyl groups of the anionic surfactant may contain, for example, about 6 to about 24 carbon atoms, or, for example, about 8 to about 22 carbon atoms, or, for example, about 12 to about 18 carbon atoms, and may be unsaturated. The aryl group in the anionic surfactant may be selected from phenyl and benzyl groups. The ether-containing anionic surfactant as set forth above may contain, for example, 1 to 10 ethylene oxide and/or propylene oxide units per surfactant molecule, or, for example, 1 to 3 ethylene oxide units per surfactant molecule.

Additional examples of the anionic surfactant may include: a sodium, potassium, lithium, magnesium, or ammonium salt of laureth sulfate, trideceth sulfate, myreth sulfate, C₁₂ to C₁₃ pareth sulfate, C₁₂ to C₁₄ pareth sulfate, or C₁₂ to C₁₅ pareth sulfate, which may be ethoxylated by ethylene oxide; or sodium, potassium, lithium, magnesium, ammonium, or triethanolamine lauryl sulfate, coco sulfate, tridecyl sulfate, myristyl sulfate, cetyl sulfate, cetearyl sulfate, stearyl sulfate, oleyl sulfate, or tallow sulfate; disodium lauryl sulfosuccinate, disodium laureth sulfosuccinate, sodium cocoyl isethionate, sodium C₁₂ to C₁₄ olefin sulfonate, sodium laureth-6 carboxylate, sodium methyl cocoyl taurate, sodium cocoyl glycinate, sodium myristyl sarcocinate, sodium dodecylbenzene sulfonate, sodium cocoyl sarcocinate, sodium cocoyl glutamate, potassium myristoyl glutamate, triethanolamine monolauryl phosphate; or a fatty acid soap including a sodium, potassium, ammonium, or triethanolamine salt of an saturated and unsaturated fatty acid that contains about 8 to about 22 carbon atoms.

More specifically, the anionic surfactant may be a sulfate-based compound having a structure represented by Formula (1).

(R¹—O)ₐ—(R²—O)_{b}—SO₃NH₄ Formula (1)

Here, a and b are each independently an integer of 0 to 120, for example, 5 to 40; a and b are not simultaneously 0; and R¹ and R² are each independently a C₁ to C₁₈ alkyl group, a C₁ to C₁₈ alkylene group, or a C₆ to C₁₄ arylene group. The C₁ to C₁₈ alkyl group, the C₁ to C₁₈ alkylene group, and the C₆ to C₁₄ arylene group may be each independently substituted or unsubstituted.

In Formula (1), the repeating unit of —R¹—O— and the repeating unit of —R²—O— may be repeated randomly or in a block form.

For example, the anionic surfactant may be a compound having a structure represented by Formula (2) or (3).

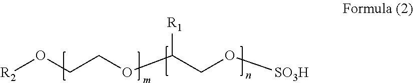

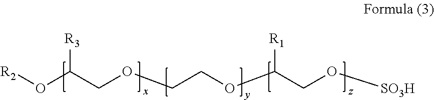

Here, m, n, x, y, and z are each independently an integer of 0 to 120, for example, an integer of 5 to 70, or an integer of 5 to 40; m and n are not simultaneously 0; x, y, and z are not simultaneously 0; and R¹, R², and R³ are each independently a C₁ to C₁₈ alkyl group, a C₁ to C₁₈ alkylene group, or a C₆ to C₁₄ arylene group. The C₁ to C₁₈ alkyl group, the C₁ to C₁₈ alkylene group, and the C₆ to C₁₄ arylene group may be each independently substituted or unsubstituted.

The anionic surfactant may be dispersed in a solvent. The solvent may be a water-based solvent or a hydrophilic solvent.

The water-based solvent may include, for example, deionized water, ultra-pure water, electrolytically ionized water, hydrogen water, and/or ozone water. The solvent may serve to control fluidity of the chemical agent. Accordingly, an amount of the solvent may be appropriately set according to desired cleaning properties such as a cleaning speed or the like. The solvent may be generally present in an amount of about 50 weight % to about 99.5 weight % in the total cleaning agent.

The hydrophilic solvent may contain, for example, at least one hydroxyl group in a molecule. For example, the hydrophilic solvent, which contains the at least one hydroxyl group in the molecule, may include a C₁ to C₈, C₂ to C₇, or C₃ to C₆ saturated aliphatic alcohol, a C₂ to C₁₆, C₃ to C₁₄, or C₅ to C₁₂ glycol, a C₄ to C₂₀, C₄ to C₁₈, or C₄ to C₁₅ glycol ether, or the like. These hydrophilic solvents may be used alone or in combination. Saturated aliphatic monohydric alcohols may include, for example, methanol, ethanol, n-propyl alcohol, isopropyl alcohol, 1-butanol, 2-butanol, isobutyl alcohol, tert-butyl alcohol, 1-pentanol, 2-pentanol, 3-pentanol, 2-methyl-1-butanol, isopentyl alcohol, sec-butyl alcohol, tert-pentyl alcohol, 3-methyl-2-butanol, neopentyl alcohol, 1-hexanol, 2-methyl-1-pentanol, 4-methyl-2-pentanol, 2-ethyl-1-butanol, 1-heptanol, 2-heptanol, 3-heptanol, 1-octanol, 2-octanol, 2-ethyl-1-hexanol, cyclohexanol, 1-methyl cyclohexanol, 2-methyl cyclohexanol, 3-methyl cyclohexanol, 4-methyl cyclohexanol, 2-ethylhexyl alcohol, or the like. The glycols may include, for example, ethylene glycol, propylene glycol, butylene glycol, hexylene glycol, diethylene glycol, dipropylene glycol, trimethylene glycol, triethylene glycol, tetramethylene glycol, tetraethylene glycol, or the like. The glycol ethers may include, for example, ethylene glycol monomethyl ether, ethylene glycol monoethyl ether, ethylene glycol mono-n-propyl ether, ethylene glycol mono-n-butyl ether, diethylene glycol monomethyl ether, diethylene glycol monoethyl ether, diethylene glycol monopropyl ether, diethylene ethylene glycol monobutyl ether, diethylene glycol monohexyl ether, triethylene glycol monomethyl ether, triethylene glycol monoethyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, tripropylene glycol monomethyl ether, 3-methoxy-3-methyl-1-butanol, or the like.

In the chemical cleaning solution, the anionic surfactant may have a concentration of about 0.0001 M to about 10 M. In particular, the anionic surfactant may have a concentration that is equal to or greater than a critical micelle concentration thereof. If the concentration of the anionic surfactant is sufficiently high, micelles may be formed, and thus, the chemical cleaning may be accomplished. In addition, if the concentration of the anionic surfactant is not excessively high, the presence of the anionic surfactant after rinsing may be avoided. There is also an advantage in an economic perspective to limiting the amount of the anionic surfactant to within the range.

The chemical cleaning solution may be adjusted to a pH of about 7 to about 10. If the pH of the chemical cleaning solution is too high, damage to a surface of the metal material film may be avoided. On the other hand, if the pH of the chemical cleaning solution is too low, a deterioration of particle removal performance thereof may be avoided.

The chemical cleaning solution may further include a pH control agent in order to adjust the pH thereof. The pH control agent may be a basic compound. For example, the pH control agent may be sodium hydroxide, potassium hydroxide, tetramethylammonium hydroxide, or the like.

The physical cleaning solution and the chemical cleaning solution may be provided onto the substrate. For example, a time period for which the physical cleaning solution is supplied may at least partially overlap a time period for which the chemical cleaning solution is supplied.

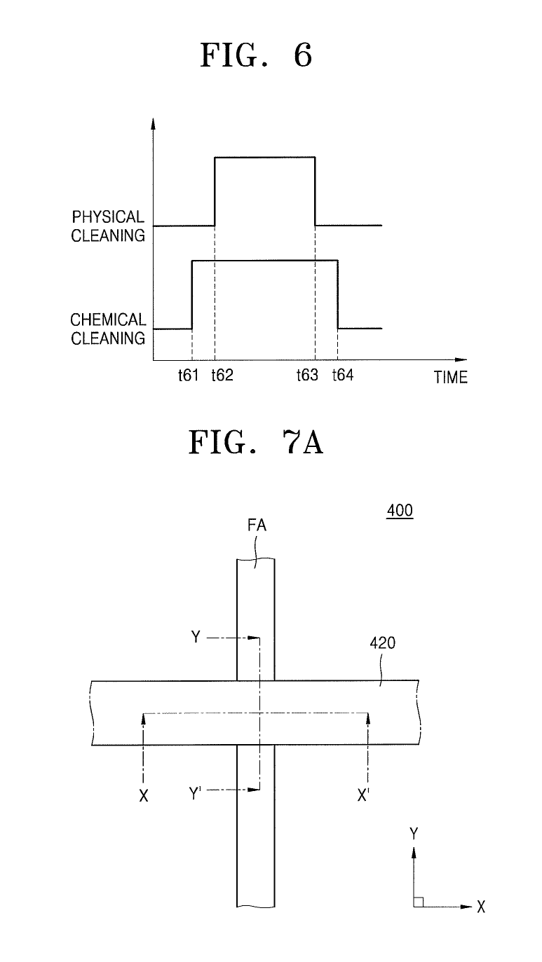

FIG. 5 illustrates a timing diagram conceptually showing a relationship between a time period for performing the physical cleaning and a time period for performing the chemical cleaning according to an embodiment.

Referring to FIG. 5, the performing of the physical cleaning and the performing of the chemical cleaning may be simultaneously started and simultaneously terminated. For example, the performing of the physical cleaning and the performing of the chemical cleaning may be equally started at time t51 and terminated at time t52.

The chemical cleaning may be continued while the physical cleaning is performed. Accordingly, a cleaning process in which the physical cleaning solution alone directly impacts on the surface of the substrate can be avoided.

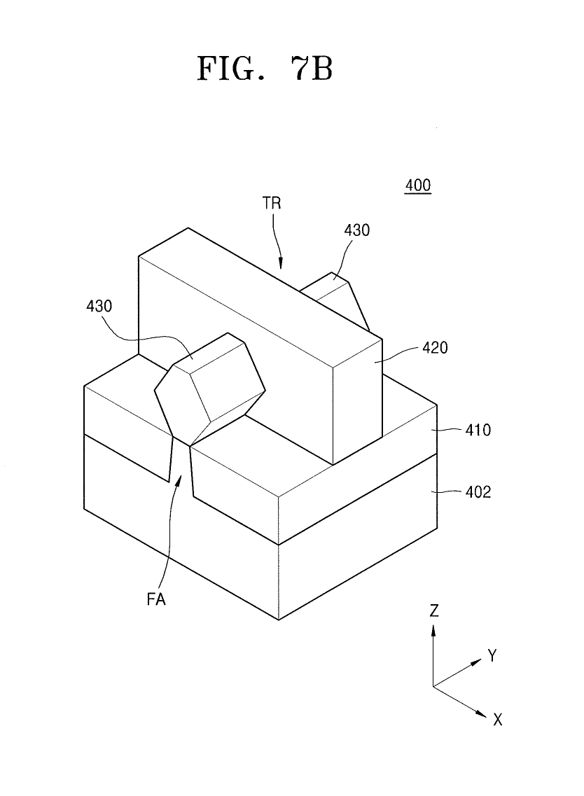

FIG. 6 illustrates a timing diagram conceptually showing a relationship between a time period for performing the physical cleaning and a time period for performing the chemical cleaning according to an embodiment.

Referring to FIG. 6, the performing of the chemical cleaning and the performing of the physical cleaning may temporally overlap each other such that the performing of the chemical cleaning is started earlier than the performing of the physical cleaning. In addition, the performing of the chemical cleaning may be terminated later than the performing of the physical cleaning. For example, after a layer of the chemical cleaning solution is formed on the surface of the substrate by starting the chemical cleaning at time t61, the physical cleaning may be started at time t62. Therefore, features on the surface of the substrate can be prevented from being damaged by a direct blow of the physical cleaning solution to the surface of the substrate.

After a liquid layer of the chemical cleaning solution is formed on the surface of the substrate by starting the chemical cleaning at the time t61, the physical cleaning may be started at the time t62. The physical cleaning and the chemical cleaning may be continued between the time t62 and time t63. After the physical cleaning is terminated at the time t63, the chemical cleaning may be further continued for some time and then terminated at time t64. The time periods of the physical cleaning and the chemical cleaning may be configured as stated above, whereby the chemical cleaning can be continued, at least while the physical cleaning is continued. For example, the chemical cleaning may be performed alone for some time before and after the physical cleaning, such that the physical cleaning may be effectively prevented from locally impacting on the substrate even for a short time.

In some embodiments, the chemical cleaning and the physical cleaning may be simultaneously terminated at the time t63. In some embodiments, the chemical cleaning and the physical cleaning may be simultaneously started at the time t62.

Referring again to FIG. 4, the substrate after completion of cleaning may be rinsed (S130). The rinsing of the substrate may include, for example, applying ultra-pure water or deionized water onto the surface of the substrate for about 10 seconds to about 30 seconds.

Next, the substrate may be dried (S140). Isopropyl alcohol (IPA) and/or nitrogen (N₂) gas may be supplied at about 20° C. to about 30° C. to dry the substrate. The isopropyl alcohol may be supplied in a liquid state at a flow rate of about 180 sccm to about 220 sccm for about 10 seconds to about 120 seconds. At this time, if the nitrogen (N₂) gas is jetted onto the surface of the substrate, the isopropyl alcohol (IPA) supplied in a liquid state may be vaporized to be removed together with a rinse solution (that is, deionized water, ultra-pure water, and the like) remaining on the substrate, such that the substrate is dried.

By use of the method of cleaning the substrate according to the embodiments, particles of various sizes may be effectively removed, and damage to features on the substrate may be minimized.

Hereinafter, examples to which the cleaning solution and the cleaning method as described above can be applied will be described.

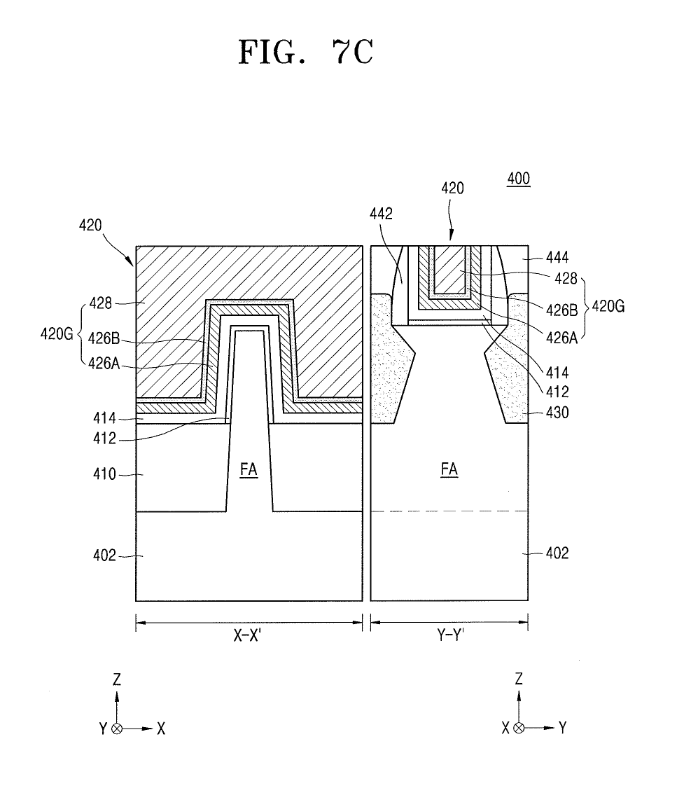

FIGS. 7A to 7C illustrate diagrams for explaining a method of fabricating an integrated circuit element according to other embodiments, FIG. 7A illustrates a plan view of the integrated circuit element intended to be formed, FIG. 7B illustrates a perspective view of the integrated circuit element of FIG. 7A, and FIG. 7C illustrates sectional views of the integrated circuit element, respectively taken along lines X-X′ and Y-Y′ of FIG. 7A.

Referring to FIGS. 7A to 7C, an integrated circuit element 400 may include a fin-type active region FA protruding from a substrate 402.

The substrate 402 may include a semiconductor such as Si or Ge, or a compound semiconductor such as SiGe, SiC, GaAs, InAs, or InP. In some embodiments, the substrate 402 may include at least one of a Group III-V material and a Group IV material. The substrate 402 may include at least one of a Group III-V material and a Group IV material. The Group III-V material may be a binary, ternary, or quaternary compound including at least one Group III atom and at least one Group V atom. The Group III-V material may be a compound including at least one atom of In, Ga, and Al as a Group III atom, and at least one atom of As, P, and Sb as a Group V atom. For example, the Group III-V material may be selected from among InP, In_{z}Ga_{1-z}As (0≦z≦1), and Al_{z}Ga_{1-z}As (0≦z≦1). The binary compound may be, for example, any one of InP, GaAs, InAs, InSb, and GaSb. The ternary compound may be, for example, any one of InGaP, InGaAs, AlInAs, InGaSb, GaAsSb, and GaAsP. The Group IV material may be Si or Ge. In another embodiment, the substrate 402 may have a silicon-on-insulator (SOI) structure. The substrate 402 may include a conductive region, for example, an impurity-doped well or an impurity-doped structure.

The substrate 402 may include the Group IV material or the Group IV material, and may be used as a channel material allowing a low-power high-speed transistor to be made. If an NMOS transistor is formed on the substrate 402, the substrate 402 may include any one of Group III-V materials. For example, the substrate 402 may include GaAs. If a PMOS transistor is formed on the substrate 402, the substrate 402 may include a semiconductor material having a higher hole mobility than a Si substrate, for example, Ge.

To clean a surface of the substrate 402, the cleaning solution and the cleaning method according to the embodiments described above may be used. If a Ge surface is cleaned using a general cleaning solution such as an SC-1 solution, such a cleaning may be disadvantageous in that a thickness loss may occur at a level of thousands of angstroms per minute. On the other hand, use of the cleaning solution and the cleaning method according to the embodiments described herein may prevent or minimize damage to a Ge material film, thereby contributing to the fabrication of a more reliable semiconductor device. For example, when the cleaning solution and the cleaning method according to the embodiments are used, a loss rate of a metal material film may be less than 10 nm per minute.

The fin-type active region FA may extend along one direction (Y direction in FIGS. 7A and 7B). An element isolation film 410 covering a lower sidewall of the fin-type active region FA may be formed on the substrate 402. The fin-type active region FA may protrude upwardly in a fin shape from the element isolation film 410. In some embodiments, the element isolation film 410 may include silicon oxide, silicon nitride, silicon oxynitride, or combinations thereof, as examples.

A gate structure 420 may extend in a direction (X direction) intersecting with the extension direction of the fin-type active region FA on the fin-type active region FA on the substrate 410. A pair of source/drain regions 430 may be formed at both sides of the gate structure 420 in the fin-type active region FA.

The pair of source/drain regions 430 may include a semiconductor layer that is epitaxially grown on the fin-type active region FA. Each of the pair of source/drain regions 430 may include an embedded SiGe structure including a plurality of epitaxially grown SiGe layers, an epitaxially grown Si layer, or an epitaxially grown SiC layer. In FIG. 7B, although the pair of source/drain regions 430 are shown as having a specific shape, the pair of source/drain regions 430 may have various sectional shapes different from what is shown in FIG. 7B. For example, the pair of source/drain regions 430 may have various sectional shapes such as circles, ellipses, polygons, or the like.

A MOS transistor TR may be formed in a portion in which the fin-type active region FA intersects with the gate structure 420. The MOS transistor TR may be a 3-dimensional structured MOS transistor in which a channel is formed on an upper surface and both side surfaces of the fin-type active region FA. The MOS transistor TR may constitute an NMOS transistor or a PMOS transistor.

When the pair of source/drain regions 430 includes an epitaxially grown SiGe layer as described above, the cleaning solution and the cleaning method according to the embodiments as described above may be used.

As shown in FIG. 7C, the gate structure 420 may include an interface layer 412, a high-K dielectric film 414, a first metal-containing layer 426A, a second metal-containing layer 426B, and a gap-fill metal layer 428, which are sequentially formed on a surface of the fin-type active region FA. The first metal-containing layer 426A, the second metal-containing layer 426B, and the gap-fill metal layer 428 of the gate structure 420 may constitute a gate electrode 420G.

An insulating spacer 442 may be formed on both side surfaces of the gate structure 420. An interlayer dielectric 444 covering the insulating spacer 442 may be formed at an opposite side to the gate structure 420 with the insulating spacer 442 interposed between the gate structure 420 and the interlayer dielectric 444.

The interface layer 412 may be formed on the surface of the fin-type active region FA. The interface layer 412 may be formed of an insulating material such as an oxide film, a nitride film, or an oxynitride film. The interface layer 412 may constitute a gate insulating film in conjunction with the high-K dielectric film 414.

The high-K dielectric film 414 may include a material having a greater dielectric constant than a silicon oxide film. For example, the high-K dielectric film 414 may have a dielectric constant of about 10 to about 25. The high-K dielectric film 414 may include a material selected from among zirconium oxide, zirconium silicon oxide, hafnium oxide, hafnium oxynitride, hafnium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof, as examples.

The high-K dielectric film 414 may be formed by an ALD process. The cleaning solution and the cleaning method according to the embodiments as described above may be used for surface cleaning after the high-K dielectric film 414 is formed.

In some embodiments, the first metal-containing layer 426A may include Ti nitride, Ta nitride, Ti oxynitride, or Ta oxynitride. For example, the first metal-containing layer 426A may include TiN, TaN, TiAlN, TaAlN, TiSiN, or combinations thereof. The first metal-containing layer 426A may be formed through various deposition methods such as ALD, CVD, PVD, or the like.

In some embodiments, the second metal-containing layer 426B may include an N-type metal-containing layer for an NMOS transistor including a Ti or Ta-containing Al compound. For example, the second metal-containing layer 426B may include TiAlC, TiAlN, TiAlCN, TiAl, TaAlC, TaAlN, TaAlCN, TaAl, or combinations thereof.

In some other embodiments, the second metal-containing layer 426B may include a P-type metal-containing layer for a PMOS transistor. For example, the second metal-containing layer 426B may include at least one of Mo, Pd, Ru, Pt, TiN, WN, TaN, Ir, TaC, RuN, and MoN.

The second metal-containing layer 426B may include a single layer or multiple layers.

The second metal-containing layer 426B may serve to adjust a work function of the gate structure 420 in conjunction with the first metal-containing layer 426A. A threshold voltage of the gate structure 420 may be adjusted by work function adjustment of the first metal-containing layer 426A and the second metal-containing layer 426B. In some embodiments, either of the first metal-containing layer 426A and the second metal-containing layer 426B can be omitted.

The gap-fill metal layer 428 may be formed to fill the remaining gate space over the second metal-containing layer 426B when the gate structure 420 is formed by a replacement metal gate (RMG) process. If the remaining gate space over the second metal-containing layer 426B is not present after the second metal-containing layer 426B is formed, the gap-fill metal layer 428 may be omitted instead of being formed on the second metal-containing layer 426B.

The gap-fill metal layer 428 may include a material selected from the group of W, metal nitrides such as TiN and TaN, Al, metal carbides, metal silicides, metal aluminum carbides, metal aluminum nitrides, metal silicon nitrides, and the like.

After the first metal-containing layer 426A, the second metal-containing layer 426B, and/or the gap-fill metal layer 428 are formed, the cleaning solution and the cleaning method according to the embodiments as described above may be used for surface cleaning.

If a TiN or W surface is cleaned using a general cleaning solution such as an SC-1 solution, such a cleaning may be disadvantageous in that a thickness loss may occur at rate of 500 angstroms or more per minute. On the other hand, use of the cleaning solution and the cleaning method according to the embodiments may prevent or minimize damage to a TiN or W material film, thereby contributing to the fabrication of a more reliable semiconductor device. For example, when the cleaning solution and the cleaning method according to the embodiments are used, a loss rate of a metal material film may be less than 10 nm per minute.

According to the method of fabricating the integrated circuit element 400 as described with reference to FIGS. 7A to 7C, to clean the surface of the substrate on which the metal material film is formed, the chemical cleaning using the chemical cleaning solution, in which the anionic surfactant is present in a concentration of the CMC or more, and the physical cleaning are simultaneously performed, whereby a more reliable semiconductor device can be fabricated due to low loss and damage of the metal material film.

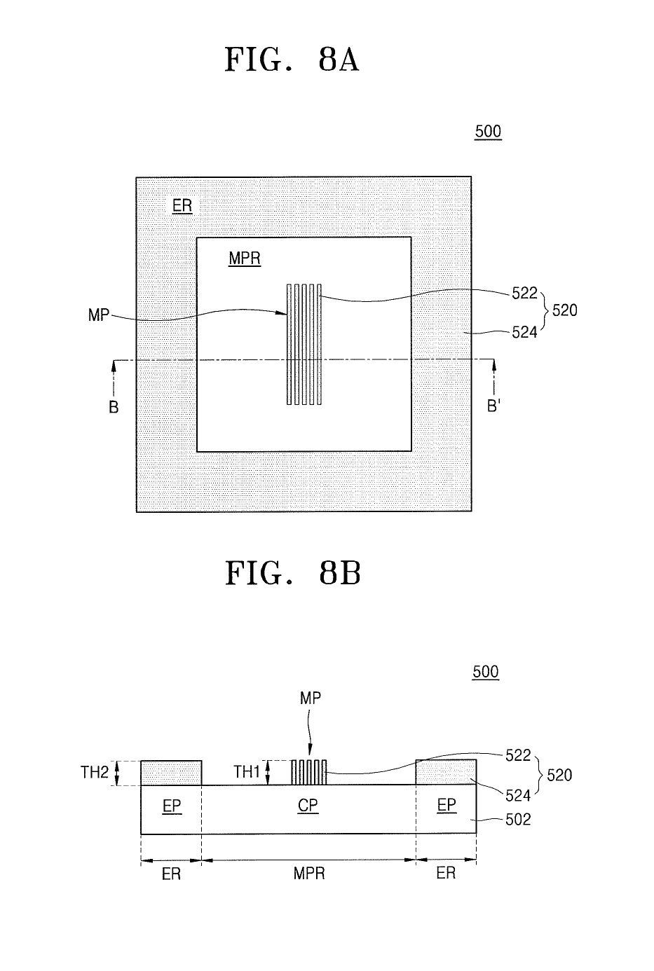

FIGS. 8A and 8B illustrate diagrams for explaining a photomask fabricated using the cleaning method according to the embodiments, FIG. 8A illustrates a plan view showing a frontside of a photomask 500, and FIG. 8B illustrates a sectional view of the photomask 500, taken along a line B-B′ of FIG. 8A.

Referring to FIGS. 8A and 8B, the photomask 500 may include a transparent substrate 502, a main pattern region MPR arranged on a central portion CP of the transparent substrate 502, and an edge region ER extending from an outer edge of the main pattern region MPR to an outer edge of the transparent substrate 502 on the transparent substrate 502.

The photomask 500 may have a form of a single layer phase shift mask (SL-PSM) in which only a phase shift pattern 520 is present on the transparent substrate 502.

In the main pattern region MPR, at least one main pattern MP, which includes a first phase shift pattern 522 corresponding to a portion of the phase shift pattern 520, is formed.

In the edge region ER, a second phase shift pattern 524, which is the other portion of the phase shift pattern 520, is formed. The second phase shift pattern 524 in the edge region ER extends from the outer edge of the main pattern region MPR to the outer edge of the transparent substrate 502.

Each of the first phase shift pattern 522 and the second phase shift pattern 524 may have a lower surface contacting the transparent substrate 502.

In some embodiments, the transparent substrate 502 may include quartz, glass, or plastic. The plastic may include a polyimide, a polyamide, a liquid crystal polyarylate, polyethylene terephthalate (PET), polyetheretherketone (PEEK), polyethersulfone (PES), polyether nitrile (PEN), a polyester, a polycarbonate, a polyarylate, a polysulfone, a polyetherimide, or the like.

The first phase shift pattern 522 and the second phase shift pattern 524 may include the same material. Each of the first phase shift pattern 522 and the second phase shift pattern 524 may include a Cr compound, a Si compound, a metal silicide compound, or combinations thereof. The Cr compound may be selected from among Cr oxide, Cr nitride, Cr carbide, Cr oxynitride, and Cr oxycarbonitride. The Si compound may be selected from among Si oxide and spin-on glass (SOG). The metal silicide compound may include: a metal, such as Mo, Ti, Ta, Zr, Hf, Nb, V, W, Co, Cr, Ni, or the like; Si; and at least one element selected from among O and N. In some embodiments, the metal silicide compound may be selected from among TaSi, MoSi, WSi, nitrides thereof, and oxynitrides thereof.

In some embodiments, each of the first phase shift pattern 522 and the second phase shift pattern 524 may include MoSiN, MoSiCN, MoSiON, MoSiCON, TaON, TiON, or combinations thereof.

A thickness TH1 of the first phase shift pattern 522 may be equal to a thickness TH2 of the second phase shift pattern 524.

In the photomask 500, the edge region ER may have a double-layer structure that only includes an edge portion EP of the transparent substrate 502 and the second phase shift pattern 524 on the edge portion EP.

After the first phase shift pattern 522 and the second phase shift pattern 524 are formed, the cleaning solution and the cleaning method according to the embodiments as described above may be used for surface cleaning.

The photomask 500 may be used for photolithography processes for fabricating various micro-electronic elements. In some embodiments, the photomask 500 may be used for fabricating micro-electronic elements such as display devices, highly integrated semiconductor memory elements including DRAMs, SRAMs, and flash memory elements, processors including central processor units (CPUs), digital signal processors (DSPs), and combinations thereof, application specific integrated circuits (ASICs), microelectromechanical systems (MEMS) elements, optoelectronic elements, and the like.

The at least one main pattern MP in the main pattern region MPR of the photomask 500 may be a pattern for transferring a pattern that configures an electronic element to an element formation region of a substrate for forming the electronic element by a photolithography process. In some embodiments, the at least one main pattern MP may include patterns for forming a pixel region, element region, chip region, or cell region of the various micro-electronic elements stated above as examples.

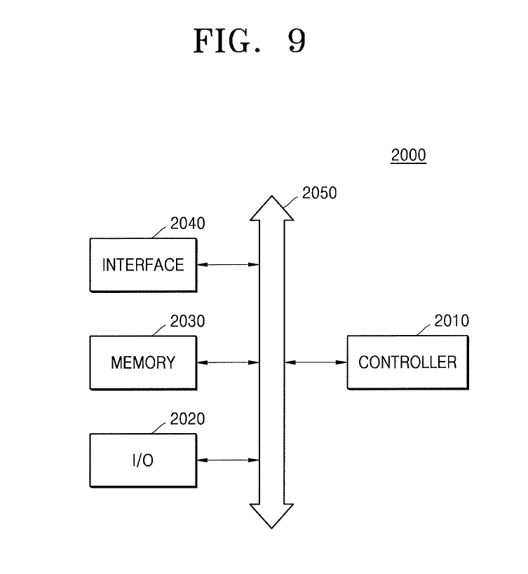

FIG. 9 illustrates a block diagram of an electronic system 2000 manufactured using a cleaning method according to embodiments.

The electronic system 2000 may include a controller 2010, an input/output (I/O) device 2020, a memory 2030, and an interface 2040. These components may be connected to one another through a bus 2050.

The controller 2010 may include at least one of a microprocessor, a digital signal processor, and a processing device similar thereto. The input/output device 2020 may include at least one of a keypad, a keyboard, and a display. The memory 2030 may be used to store commands executed by the controller 2010. For example, the memory 2030 may be used to store user data.

The electronic system 2000 may constitute a wireless communication device, or a device capable of transmitting and/or receiving information in a wireless environment. In the electronic system 2000, to transmit and/or receive data through a wireless communication network, the interface 2040 may be configured as a wireless interface. The interface 2040 may include an antenna and/or a wireless transceiver. In some embodiments, the electronic system 2000 may be used for a communication interface protocol of a third generation (3G) communication system, such as code division multiple access (CDMA), global system for mobile communications (GSM), North American digital cellular (NADC), extended-time division multiple access (E-TDMA), and/or wide band code division multiple access (WCDMA) systems. The electronic system 2000 may include a thin film formed using the cleaning method according to embodiments described above, or the integrated circuit element 400 fabricated using the thin film.

By way of summation and review, physical cleaning may be effective for removing contamination particles having a relatively large size, for example, a size of 65 nm or more. However, physical cleaning by itself t may have a low particle removal efficiency (PRE) for contamination particles having a size less than 65 nm. In addition, physical cleaning may have a significantly deteriorating effect in cleaning fine particles having a size that is less than 65 nm. To address this issue, chemical cleaning may be simultaneously performed with chemical cleaning.

A standard clean (SC-1) solution (generally, an ammonia peroxide mixture) is widely used as a cleaning solution in a semiconductor cleaning process. The SC-1 solution allows particles to be removed by providing a repulsive force after surface etching. Accordingly, although the SC-1 solution efficiently removes particles, the SC-1 may cause damage to a film quality due to surface etching. Thus, it may be disadvantageous to use a SC-1 solution as a cleaning solution for various films.

Embodiments provide a method of cleaning a substrate that can efficiently remove particles of all sizes and can minimize damage to features on the substrate. Embodiments provide a method of fabricating a semiconductor device that can efficiently remove particles of all sizes and can minimize damage to features on the substrate, and to a method of fabricating a semiconductor device using the same

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. A method of cleaning a substrate, the method comprising:
providing the substrate, the substrate including a metal material film;
performing physical cleaning of the substrate;
performing chemical cleaning of the substrate; and
drying a surface of the substrate,
wherein performing the chemical cleaning includes supplying a chemical cleaning solution including an anionic surfactant at a concentration that is equal to or greater than a critical micelle concentration (CMC) onto the surface of the substrate.

2. The method as claimed in claim 1, wherein the anionic surfactant is a sulfate-based surfactant.

3. The method as claimed in claim 2, wherein the anionic surfactant has a structure represented by Formula (1):
(R¹—O)ₐ—(R²—O)_{b}—SO₃NH₄ Formula (1)
wherein:
a and b are each independently an integer of 0 to 120;
a and b are not simultaneously 0;
R¹ and R² are each independently a C₁ to C₁₈ alkyl group, a C₁ to C₁₈ alkylene group, or a C₆ to C₁₄ arylene group;
the C₁ to C₁₈ alkyl group, the C₁ to C₁₈ alkylene group, and the C₆ to C₁₄ arylene group are each independently substituted or unsubstituted; and
the repeating unit of —R¹—O— and the repeating unit of —R²—O— are repeated randomly or in a block form.

4. The method as claimed in claim 2, wherein the anionic surfactant has a structure represented by Formula (2) or (3): 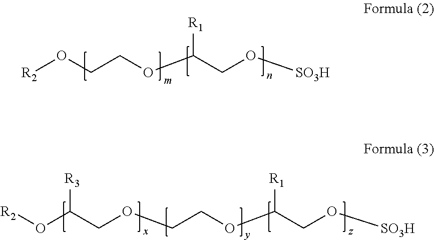
wherein:
m, n, x, y, and z are each independently an integer of 0 to 120;
m and n are not simultaneously 0;
x, y, and z are not simultaneously 0;
R¹, R², and R³ are each independently a C₁ to C₁₈ alkyl group, a C₁ to C₁₈ alkylene group, or a C₆ to C₁₄ arylene group; and
the C₁ to C₁₈ alkyl group, the C₁ to C₁₈ alkylene group, and the C₆ to C₁₄ arylene group are each independently substituted or unsubstituted.

5. The method as claimed in claim 1, wherein performing the physical cleaning at least partially overlaps performing the chemical cleaning.

6. The method as claimed in claim 5, wherein the metal material film includes at least one selected from the group of germanium (Ge), hafnium (Hf), titanium (Ti), tantalum (Ta), tungsten (W), chromium (Cr), gold (Au), silver (Ag), platinum (Pt), palladium (Pd), rhodium (Rh), aluminum (Al), nickel (Ni), molybdenum (Mo), niobium (Nb), zirconium (Zr), strontium (Sr), alloys thereof, nitrides thereof, oxides thereof, and oxynitrides thereof.

7. The method as claimed in claim 5, wherein:
the physical cleaning and the chemical cleaning are simultaneously performed, and
performing the physical cleaning includes supplying a physical cleaning solution onto a liquid layer of a chemical cleaning solution.

8. The method as claimed in claim 7, wherein performing the chemical cleaning is terminated simultaneously with or after termination of performing the physical cleaning.

9. The method as claimed in claim 7, wherein during performing the chemical cleaning:
the substrate is rotated,
the chemical cleaning solution is supplied toward a center of rotation of the substrate, and
the liquid layer of the chemical cleaning solution is formed on the surface of the substrate by the rotation of the substrate.

10. The method as claimed in claim 1, wherein the supplied chemical cleaning solution has a pH of about 7 to about 10.

11. The method as claimed in claim 1, wherein the anionic surfactant supplied onto the surface of the substrate has a concentration of about 0.0001 M to about 10 M in the cleaning solution.

12. A method of fabricating a semiconductor device, the method comprising:
forming a metal material film on a substrate;
cleaning the substrate;
rinsing the substrate; and
drying the substrate,
wherein cleaning the substrate includes simultaneously performing physical cleaning and chemical cleaning, and
the chemical cleaning includes supplying a cleaning solution including an anionic surfactant.

13. The method as claimed in claim 12, wherein the anionic surfactant is supplied at a concentration that is equal to or greater than a critical micelle concentration (CMC).

14. The method as claimed in claim 13, wherein the metal material film experiences a loss rate by the chemical cleaning that is less than 10 nm/min.

15. The method as claimed in claim 14, wherein, in cleaning the substrate, a particle removal efficiency (PRE) for particles having a size that is less than 65 nm is 85% or more.

16. A method of fabricating a semiconductor device, the method comprising:
providing a substrate, the substrate including a metal material film;
conducting a semiconductor device fabrication process on the metal material film;
cleaning the substrate;
wherein:
the cleaning of the substrate includes simultaneously performing physical cleaning and chemical cleaning,
the chemical cleaning includes supplying a chemical cleaning solution including an anionic surfactant to the substrate from a chemical cleaning solution supplier, and
the physical cleaning includes supplying a physical cleaning solution to the substrate from a physical cleaning solution supplier, the physical cleaning solution supplier being different from the chemical cleaning solution supplier, and
the chemical cleaning is begun before or at a same time that the physical cleaning is begun and the chemical cleaning is ended after or at a same time that the physical cleaning is ended.

17. The method as claimed in claim 16, wherein the semiconductor device fabrication process is a patterning process that patterns the metal material film.

18. The method as claimed in claim 16, wherein:
the anionic surfactant is included in the chemical cleaning solution at a concentration that is equal to or greater than a critical micelle concentration (CMC), and
the chemical cleaning solution has a pH of about 7 to about 10.

19. The method as claimed in claim 16, wherein, in cleaning the substrate:
the substrate is rotated,
the chemical cleaning solution is supplied toward a center of rotation of the substrate, such that the liquid layer of the chemical cleaning solution is formed on the surface of the substrate by the rotation of the substrate, and
the physical cleaning solution is supplied onto the liquid layer of the chemical cleaning solution on the substrate.
